(19) United States
(12) Patent Application Publication
(10) Pub. No.: US 2022/0403240 A1
(43) Pub. Date: Dec. 22, 2022

(54) QUANTUM DOT AND PREPARATION METHODS FOR THE SAME, AND PHOTOELECTRIC DEVICE

(71) Applicant: Najing Technology Corporation Limited, Hangzhou, Zhejiang (CN)

(72) Inventors: Baozhong HU, Hangzhou, Zhejiang (CN); Yuan GAO, Hangzhou, Zhejiang (CN); Yanhong MAO, Hangzhou, Zhejiang (CN); Guangxu LI, Hangzhou, Zhejiang (CN)

(21) Appl. No.: 17/777,657

(22) PCT Filed: Nov. 20, 2020
(86) PCT No.: PCT/CN2020/130633

§ 371 Date: May 18, 2022

(30) Foreign Application Priority Data
Nov. 21, 2019 (CN) 201911147636.8

(51) Int. Cl. C09K 11/88; H01L 51/50; H01L 33/50; C09K 11/56; B82Y 40/00

(52) U.S. Cl. CPC C09K 11/883; H01L 51/502; H01L 33/502; C09K 11/565; B82Y 40/00

(57) ABSTRACT

The present disclosure relates to a quantum dot and a preparation method for the same, and a photoelectric device. The quantum dot includes a core and a shell layer coating the core, a material of the core is CdZnSe, and a material of the shell layer is CdZnS, wherein, a molar ratio of Cd element with respect to S element in the shell layer is from 0.15:1 to 0.4:1.

The present application is a National Stage of International Patent Application No. PCT/CN2020/130633 filed on Nov. 20, 2020, the disclosures of which is incorporated by reference in their entirety.

### TECHNICAL FIELD

The present disclosure relates to the technical field of quantum dots, particularly relates to a quantum dot and preparation methods for the same, and a photoelectric device.

### BACKGROUND

At present, external quantum efficiency (EQE) of the devices using blue quantum dots such as CdZnS/ZnS, CdZnS/ZnS, ZnCdSe/ZnS has reached more than 10%, and the maximum brightness has exceeded 10,000 cd/m². However, these blue quantum dots are covered with thick ZnS shell as the outer layer, which results in the deep HOMO (highest occupied molecular orbital) energy level (i.e. large absolute value) and high LUMO (lowest unoccupied molecular orbital) energy level of blue quantum dots, which is not favorable for effective carrier injection, so that the lifetime of the photoelectric devices having these blue quantum dots will generally not exceed 1000 hours, which is far from meeting the minimum requirements for commercialization.

In addition, in the prior art, it is proposed that coating ZnCdSe with ZnSe shell of about 7 nm thickness can effectively improve the HOMO level of blue quantum dots and shorten the energy level gap with the TFB material in hole transport layer, so that the photoelectric device applying this kind of blue quantum dot can achieve a lifetime of 7000 h at a luminance of 100 cd/m², compared with the quantum dots coated by ZnS shell, this lifetime is significantly improved. However, the photoelectric device applying this kind of blue quantum dot would achieve the maximum external quantum efficiency (EQE) requires a luminance of 10000 cd/m², and the working current density of the photoelectric device is 88 mA/cm². So, under a luminance of 50˜200 cd/m² of the actual commercialization requirement, EQE of the photoelectric device applying this kind of blue quantum dots will be attenuated to 3%, which is extremely low and far from meeting the commercialization requirements.

### SUMMARY

In one aspect of the present disclosure, there is provided a quantum dot, including a core and a shell layer covering the core, a material of the core being CdZnSe, and a material of the shell layer being CdZnS, wherein a molar ratio of Cd element with respect to S element in the shell layer is from 0.15:1 to 0.4:1.

Optionally, an average particle diameter of the core is from 3 nm to 10 nm, and a thickness of the shell layer is from 3 nm to 10 nm.

Optionally, the average particle diameter of the core is from 5 nm to 9 nm, and the thickness of the shell layer is from 3 nm to 5 nm.

Optionally, a photoluminescence emission peak wavelength of the quantum dot is from 460 nm to 480 nm.

Optionally, the photoluminescence emission peak wavelength of the quantum dot is from 470 nm to 480 nm.

In another aspect of the present disclosure, there is provided a preparation method for the above quantum dots, including: preparing cores; mixing the cores, a zinc precursor, an aliphatic amine and a solvent to form a first precursor solution, and then at a constant speed adding a first cadmium precursor and a first sulfur precursor separately or together to the first precursor solution to form a second precursor solution, wherein a molar ratio of Cd element with respect to S element in the second precursor solution is from 0.15:1 to 0.4:1; performing a reaction of the second precursor solution at a first temperature to form a shell layer covering a surface of the core, and obtaining the quantum dots.

Optionally, the process of preparing the cores including: mixing a second zinc precursor, a first selenium precursor, a second cadmium precursor and a solvent, reacting at a second temperature to obtain a solution containing first alloy quantum dots, and purifying the first alloy quantum dots for use as the cores.

Optionally, the process of preparing the cores further including: after the reaction at the second temperature, adding a second selenium precursor, and reacting at a third temperature to obtain a solution containing the first alloy quantum dots.

Optionally, the process of preparing the cores further including:

(1) using the solution containing the first alloy quantum dots as a first intermediate solution;

(2) mixing the first intermediate solution, a short-chain aliphatic acid zinc having a carbon chain length less than or equal to 8, and a long-chain aliphatic acid having a carbon chain length greater than or equal to 12, and reacting at a fourth temperature to obtain a second intermediate solution;

(3) mixing the second intermediate solution and a third selenium precursor, and reacting at a fifth temperature, so that the first alloy quantum dots can continue to grow, obtaining a solution containing second alloy quantum dots;

(4) purifying the second alloy quantum dots for use as the cores.

Optionally, repeating the step (2) and the step (3) at least n times to continue to grow, at nth repetition, replacing the first intermediate solution of the step (1) with a solution of (n+1)th alloy quantum dots to obtain a solution containing (n+2)th alloy quantum dots, and purifying the (n+2)th alloy quantum dots for use as the cores, wherein the n is a positive integer greater than or equal to 1.

Optionally, a molar ratio of the long-chain aliphatic acid with respect to the short-chain aliphatic acid zinc is greater than or equal to 2:1.

Optionally, the molar ratio of the long-chain aliphatic acid with respect to the short-chain aliphatic acid zinc is from 2:1 to 4:1.

Optionally, a molar ratio of selenium element in the third selenium precursor with respect to zinc element in the second intermediate solution is from 1:2 to 2:1, and a molarity of the selenium element in the third selenium precursor is from 0.5 mmol/mL to 4 mmol/mL.

Optionally, after the first alloy quantum dots growing into the second alloy quantum dots, a thickness of growth is less than or equal to 1.5 nm; and after the (n+1)th alloy quantum dots growing into the (n+2)th alloy quantum dots, a thickness of growth is less than or equal to 1.5 nm for each repetition.

Optionally, at ith repetition, replacing the first intermediate solution of the step (1) with a solution of (i+1)th alloy quantum dots to obtain a solution containing (i+2)th alloy quantum dots, and purifying the (i+2)th alloy quantum dots for use as the cores, wherein the i is a positive integer less than the n.

In another aspect of the present disclosure, there is provided a preparation method for quantum dots, including: preparing cores; mixing the cores, a zinc precursor, an aliphatic alcohol and a solvent to form a first precursor solution, and then at a constant speed adding a first cadmium precursor and a first sulfur precursor separately or together to the first precursor solution to form a second precursor solution, wherein a molar ratio of Cd element with respect to S element in the second precursor solution is from 0.15:1 to 0.4:1; performing a reaction of the second precursor solution at a first temperature to form a shell layer covering a surface of the core, and obtaining the quantum dots.

Optionally, the aliphatic alcohol is selected from the group of aliphatic alcohols with carbon chain length of 12 to 30.

In another aspect of the present disclosure, there is provided a quantum dot composition, including the aforesaid quantum dot, or the quantum dots prepared by the aforesaid preparation method.

In another aspect of the present disclosure, there is provided a photoelectric device, including the aforesaid quantum dot, or the quantum dots prepared by the aforesaid preparation method.

Optionally, the photoelectric device is a quantum dot light emitting diode, a working current density required for the quantum dot light emitting diode to achieve the highest external quantum efficiency is from 5 mA/cm² to 20 mA/cm², and the highest external quantum efficiency is from 9.6% to 12.6%.

The quantum dot of the present disclosure adopts CdZnSe material with shallow HOMO level as the core, which can be more conducive to hole injection, and adopts the CdZnS material with low LUMO level as the shell, and the molar ratio of Cd element with respect to S element in the shell layer is from 0.15:1 to 0.4:1, making a good energy structure and more conducive to electron injection. Therefore, the carrier injection barrier of the quantum dot of this disclosure is lower, which is more conducive to carrier injection.

Furthermore, after the quantum dot is applied to the photoelectric device, the EQE can reach its maximum value under a working current density ranging from 5 to 20 mA/cm², and the maximum EQE can reach 9.6% to 12.6%. At the same time, due to the low working current density required by the photoelectric device, the lifetime of the photoelectric device is longer, and it is easier to meet the actual commercialization requirements of blue QLED.

### BRIEF DESCRIPTION OF THE DRAWINGS

The drawings constituting a portion of the present disclosure are used to provide a further understanding of the present disclosure, and the schematic embodiment of the present disclosure and the description thereof are for explaining the present disclosure, and does not constitute an improper limitations of the present disclosure. In the drawings:

FIG. 1 shows the current density-EQE graph of the quantum dot light emitting diode of Example 1.

FIG. 2 shows the current density-EQE graph of the quantum dot light emitting diode of Example 2.

FIG. 3 shows the current density-EQE graph of the quantum dot light emitting diode of Example 3.

FIG. 4 shows the current density-EQE graph of the quantum dot light emitting diode of Example 4.

FIG. 5 shows the current density-EQE graph of the quantum dot light emitting diode of Example 5.

FIG. 6 shows the current density-EQE graph of the quantum dot light emitting diode of Example 6.

FIG. 7 shows the current density-EQE graph of the quantum dot light emitting diode of Example 7.

FIG. 8 shows the current density-EQE graph of the quantum dot light emitting diode of Example 8.

FIG. 9 shows the current density-EQE graph of the quantum dot light emitting diode of Comparative Example 1.

FIG. 10 shows the current density-EQE graph of the quantum dot light emitting diode of Comparative Example 2.

FIG. 11 shows the current density-EQE graph of the quantum dot light emitting diode of Comparative Example 3.

FIG. 12 shows the current density-EQE graph of the quantum dot light emitting diode of Comparative Example 4.

### DETAILED DESCRIPTION

The quantum dot, the preparation methods for the same, the quantum dot composition, and the photoelectric device provided in this disclosure will be further described below.

As used herein, the singular forms “a,” “an” and “the” are intended to include the plural forms as well, unless the context clearly indicates otherwise.

It should be noted that the terms “first”, “second”, and the like in the specification and claims of the present disclosure are used to distinguish similar objects, and are not necessarily used to describe a particular order or sequence. It should be understood that the number so used may be interchangeable when appropriate to facilitate the description of embodiments of the invention disclosed herein. Furthermore, the terms “include” and “have”, as well as any variants thereof, are intended to cover a non-exclusive inclusion, for example, processes, methods, systems, products, or devices that include a series of steps or units are not necessarily limited to include those steps or units explicitly listed, and may include other steps or units not explicitly listed or inherent to such processes, methods, products or devices.

After long-term and in-depth researches, the applicant of the present disclosure has found that the essential reason for the failure of the existing blue quantum dots to meet the commercialization requirements is as follows: the gap between the energy level structure of existing blue quantum dots and the material of transport layer is too large, so that only at a high electric field or current density can the carrier be injected smoothly and can the luminance of the device reach the maximum value. While under the working condition of low current density, the carrier injection can be very difficult and unbalanced, which directly leads to the serious attenuation of the external quantum efficiency.

The present disclosure provides a quantum dot whose energy level structure can better match a hole transport layer and an electron transport layer, including a core and a shell layer covering the core, a material of the core being CdZnSe, and a material of the shell layer being CdZnS, wherein a molar ratio of Cd element with respect to S element in the shell layer is from 0.15:1 to 0.4:1.

It should be noted that by controlling the amount and speed of the addition of each precursor in the present disclosure, and due to the high reactivity of Cd element, almost all of the Cd element and S element in the raw material can be consumed by the reaction at the end of the reaction, therefore, the molar ratio of Cd element with respect to S element in the shell layer can be determined by the molar ratio of Cd element to S element in the added raw material (i.e. the second precursor solution described below), obtaining the shell layer where the molar ratio of Cd element with respect to S element is from 0.15:1 to 0.4:1. In some embodiments, the molar ratio of Cd element and S element in the shell layer can be obtained by ICP analysis.

Specifically, compared with ZnS, CdZnS material has a lower LUMO energy level, so when CdZnS material is used as the shell, it is more conducive to electron injection. More importantly, after long-term and in-depth researches, the applicant of this disclosure has found that when CdZnS material is used as a shell, the content of Cd element directly affects the band structure of CdZnS shell, and the band structure of CdZnS shell directly affects the performance of the photoelectric device applying such quantum dot.

Further, when the molar ratio of Cd element with respect to S element in the CdZnS shell layer is between 0.15:1 and 0.4:1, the band structure of the CdZnS shell layer is better, and the LUMO energy level is lower, which is more favorable for electron injection, and the effect becomes more significant with the increase of the molar ratio of Cd element.

In addition, compared with CdZnS material and CdZnSe material, CdZnSe material has more shallow HOMO energy level, thus CdZnSe material as the core is more conducive to hole injection.

More importantly, the core of CdZnSe material has a better matching relationship with the CdZnS shell layer which has the aforesaid molar ratio about element. Therefore, the quantum dot with CdZnSe as the core and CdZnS as the shell layer has lower carrier injection barrier and is more conducive to carrier injection. After the quantum dot is applied to the photoelectric device, the electroluminescence efficiency of the photoelectric device is higher, the working current density is lower, and the lifetime is longer, which is easier to meet the actual commercialization requirements.

In some embodiments, the shell layer is a homogeneous CdZnS shell layer, which means the Cd element is uniformly distributed in the shell to make the band structure of the shell better. When evaluating whether the shell layer is homogeneous, due to the limitation of the current technology level, we can refer to the adding means of raw materials in the preparation method for quantum dots.

Considering the effect of quantum dots in the photoelectric device, in some embodiments, an average particle size of the core is from 3 nm to 10 nm, and a thickness of the shell layer is from 3 nm to 10 nm.

In some embodiments, the average particle size of the core is from 5 nm to 9 nm, and the thickness of the shell layer is from 3 nm to 5 nm. The quantum dots having the same particle size of the core but with different thickness of the shell layer, have similar effect on the photoelectric device, but may have different emission peak wavelengths.

The quantum dots prepared in the same batch may have a relatively constant particle shape, and the average particle size is measured by transmitting electron microscope, but is not limited thereto. When the quantum dots have a spherical shape, the average particle size of the quantum dots can be diameter. When the quantum dots are non-spherical particles, the average particle size of the quantum dots can be derived from the diameter of the circle with equivalent (equal) area calculated from the two-dimensional area of the electron microscope image of the quantum dots. The thickness of the shell layer can be obtained by measuring the average particle size of the quantum dots coated with the shell layer, and then subtracting the average particle size of the corresponding core.

In some embodiments, a photoluminescence emission peak wavelength of the quantum dots is from 460 nm to 480 nm to ensure that the quantum dot is a blue quantum dot. In some embodiments, the photoluminescence emission peak wavelength of the quantum dots is preferably from 470 nm to 480 nm.

It is understood that the photoluminescence emission peak wavelength is the wavelength corresponding to the maximum peak value of the photoluminescence (PL) spectrum of a sample.

The present disclosure also provides a preparation method for quantum dots, including:

S1, preparing cores;

S2, mixing the cores, a zinc precursor, an aliphatic amine and a solvent to form a first precursor solution, and then at a constant speed adding a first cadmium precursor and a first sulfur precursor separately or together to the first precursor solution to form a second precursor solution, wherein a molar ratio of Cd element with respect to S element in the second precursor solution is from 0.15:1 to 0.4:1;

S3, performing a reaction of the second precursor solution at a first temperature to form a shell layer covering a surface of the core, and obtaining the quantum dots.

It should be noted that the “at a constant speed” mentioned in this disclosure is not an absolute constant velocity, and the mole amounts of the precursor added during the time interval of addition may have an allowable error within the range of ±10%.

In some embodiments, in the step S1, the process of preparing the cores includes: mixing a second zinc precursor, a first selenium precursor, a second cadmium precursor and a solvent, reacting at a second temperature to obtain a solution containing first alloy quantum dots, and purifying the first alloy quantum dots for use as the cores.

In some embodiments, the second zinc precursor includes a long-chain aliphatic acid zinc having a carbon chain length greater than or equal to 12. In some embodiments, the second zinc precursor may include a short-chain aliphatic acid zinc having a carbon chain length less than or equal to 8 and a long-chain aliphatic acid having a carbon chain length greater than or equal to 12, wherein the short-chain aliphatic acid zinc having a carbon chain length less than or equal to 8 includes at least one of zinc formate, zinc acetate, zinc propionate and zinc butyrate, preferably includes at least one of zinc formate, zinc acetate, and zinc propionate. The long-chain aliphatic acid having a carbon chain greater than or equal to 12 includes at least one of oleic acid, stearic acid and isostearic acid. The reaction of the two can produce the long-chain aliphatic acid zinc having a carbon chain greater than or equal to 12.

In some embodiments, the first selenium precursor includes at least one of Se-ODE (octadecene-selenium), Se-TOP (selenium-trioctylphosphine), Se-TBP (selenium-tributylphosphine), and Se-DPP (selenium-diphenylphosphine), but is not limited thereto.

In some embodiments, the second cadmium precursor can be an aliphatic acid cadmium having a carbon chain greater than 12, including at least one of cadmium dodecanoate, cadmium tetradecanoate, cadmium stearate, and cadmium oleate, but is not limited thereto.

In some embodiments, the solvent may be, but not limited to C6˜C22 alkyl primary amine, such as hexadecylamine, C6˜C22 alkyl secondary amine, such as dioctylamine, C6˜C40 alkyl tertiary amine, such as trioctylamine, nitrogenous heterocyclic compound, such as pyridine, C6˜C40 olefin, such as octadecene, C6˜C40 aliphatic hydrocarbon, such as hexadecane, octadecane or squalane, an aromatic hydrocarbon substituted by a C6˜C30 alkyl group, such as phenyldodecane, phenyltetradecane, or phenylhexadecane, a phosphine substituted by a C6˜C22 alkyl group, such as trioctylphosphine, a phosphine oxide substituted by an alkyl group of C6˜C22, such as trioctylphosphine oxide, C12-C22 aromatic ether, such as phenyl ether or benzyl ether, or a combination thereof. The solvent used for shell preparation and the solvent used for core preparation may be the same or different.

In some embodiments, the second temperature is from 280° C. to 310° C.

In some embodiments, the process of preparing the cores further includes: after the reaction at the second temperature, adding a second selenium precursor, and reacting at a third temperature to obtain a solution containing the first alloy quantum dots. In this process, the second selenium precursor can completely dissolve the unreacted first selenium precursor, and increase the selenium content in the mixture, so as to avoid the photoluminescence emission peak wavelength of CdZnSe quantum dots beyond the range of blue light.

In some embodiments, the third temperature may be the same or different from the second temperature, and the third temperature is from 300° C. to 315° C. In a preferred embodiment, the third temperature is 310° C. Within the above temperature range, CdZnSe quantum dots can be alloyed completely at high temperature, and quantum yield of CdZnSe quantum dots can be improved.

In some embodiments, organic phosphine is contained in the second selenium precursor, so that the unreacted selenium can be quickly dissolved, and the second selenium precursor includes at least one of Se-TOP, Se-TBP, and Se-DPP, but not limited thereto.

In CdZnSe quantum dot, the content of Cd element can affect the emission peak wavelength of CdZnSe quantum dot, in order to obtain the CdZnSe quantum dot having emissive wavelength ranging from 460 nm to 480 nm or from 470 nm to 480 nm, in some embodiments, the sum of the molar amount of selenium element in the first selenium precursor and the second selenium precursor ranges from 0.5 mmol to 1.5 mmol, and the molar ratio of cadmium element in the second cadmium precursor with respect to the sum of the molar amount of selenium element in the first selenium precursor and the second selenium precursor is less than or equal to 0.48:1.

In some embodiments, an average particle size of CdZnSe quantum dot is from 3.0 nm to 5.5 nm.

In some embodiments, the process of preparing the cores further includes:

(1) using the solution containing the first alloy quantum dots as a first intermediate solution;

(2) mixing the first intermediate solution, a short-chain aliphatic acid zinc having a carbon chain length less than or equal to 8, and a long-chain aliphatic acid having a carbon chain length greater than or equal to 12, and reacting at a fourth temperature to obtain a second intermediate solution;

(3) mixing the second intermediate solution and a third selenium precursor, and reacting at a fifth temperature, so that the first alloy quantum dots can continue to grow, obtaining a solution containing second alloy quantum dots;

(4) purifying the second alloy quantum dots for use as the cores.

In the step (1) of the process of preparing the cores, the solution containing the first alloy quantum dots synthesized by solution method is directly used as the first intermediate solution, not only can omit the purification step of the first alloy quantum dots, simplify operation, improve the production efficiency, also can prevent the bare first alloy quantum dots which are regarded as raw materials of the cores from being slowly oxidized by the air, thereby reducing the internal defects of the quantum dots.

In the step (2) of the process of preparing the cores, the short-chain aliphatic acid zinc and the long-chain aliphatic acid are mixed, and during the reaction at the fourth temperature, the long-chain aliphatic acid will be reacted with the short-chain aliphatic acid zinc, specifically, the long-chain aliphatic acid can replace the short-chain aliphatic acid radical in the short-chain aliphatic acid zinc to form the long-chain aliphatic acid zinc. Wherein, the long-chain aliphatic acid zinc as a precursor of the Zn element in the quantum dot core is present in the solution, while the short-chain aliphatic acid radical produced by replacement can form a short-chain aliphatic acid, such as formic acid, acetic acid, propionic acid, butyl acid, etc., which can decompose the oxidation products located on the surface of the quantum dots to reduce the internal defects of the quantum dots.

In some embodiments, the short-chain aliphatic acid zinc includes at least one of zinc formate, zinc acetate, zinc propionate, and zinc butyrate, but is not limited thereto, preferably the short-chain aliphatic acid zinc is at least one of zinc formate, zinc acetate, and zinc propionic. The long-chain aliphatic acid includes at least one of oleic acid, stearic acid, and isostearic acid, but is not limited thereto.

Considering that zinc ion is a divalent ion, each short-chain aliphatic acid zinc contains two short-chain aliphatic acid radicals, in order to fully replace the long-chain aliphatic acid zinc with the short-chain aliphatic acid zinc, in some embodiments, the molar ratio of the long-chain aliphatic acid relative to the short-chain aliphatic acid zinc is greater than or equal to 2:1. In some embodiments, the molar ratio of the long-chain aliphatic acid relative to the short-chain aliphatic acid zinc is from 2:1 to 4:1.

In addition, in order to fully replace the short-chain aliphatic acid zinc with the long-chain aliphatic acid zinc, the fourth temperature needs to be greater than the boiling point of the short-chain aliphatic acid, in some embodiments, the fourth temperature is from 100° C. to 240° C., which can be adjusted according to the boiling point of the short-chain aliphatic acid.

In the step (3) of the process of preparing the cores, during the reaction at the fifth temperature, the long-chain aliphatic acid zinc in the second intermediate solution reacts with the third selenium precursor, and the product continues to grow on the surface of the first alloy quantum dots to obtain the second alloy quantum dots.

In some embodiments, the fifth temperature is from 280° C. to 310° C.

In some embodiments, the step (2) and the step (3) are repeated at least n times for further growing, at nth repetition, the first intermediate solution of the step (1) is replaced with a solution of (n+1)th alloy quantum dots to obtain a solution containing (n+2)th alloy quantum dots, and the (n+2)th alloy quantum dots are purified for use as the cores, wherein the n is a positive integer greater than or equal to 1.

In some embodiments, at ith repetition, the first intermediate solution of the step (1) is replaced with a solution of (i+1)th alloy quantum dots to obtain a solution containing (i+2)th alloy quantum dots, and the (i+2)th alloy quantum dots are purified for use as the cores, wherein the i is a positive integer less than the n.

That is, when n is 1, the first intermediate solution of the step (1) of the process of preparing the cores is replaced with the solution of the second alloy quantum dots to obtain a solution containing third alloy quantum dots, and the third alloy quantum dots are purified for use as the cores; when n is 2, at the first repetition, the first intermediate solution of the step (1) is replaced with the solution of the second alloy quantum dots to obtain a solution containing third alloy quantum dots, and at the second repetition, the first intermediate solution of the step (1) is replaced with the solution of the third alloy quantum dots to obtain a solution containing fourth alloy quantum dots, and the fourth alloy quantum dots are purified for use as the cores. When n is greater than 2, it is similar to the repeated process described above, and no longer further described here.

Thus, by repeating the step (2) and step (3) of the preparation process of the cores, CdZnSe quantum dot cores are obtained by the means of multiple continuous preparation, which can reduce the amount of the short-chain aliphatic acid zinc used at a single repetition, and ensure that the short-chain aliphatic acid zinc in the reaction system is not excessive, so that the excessive accumulation of the formed long-chain aliphatic acid zinc can be effectively avoided, reducing the probability of decomposition of the long-chain aliphatic acid zinc at high temperature to generate oxidation products, and minimizing the internal defects of CdZnSe quantum dots. In addition, when the short-chain aliphatic acid zinc and the long-chain aliphatic acid are added in situ, formic acid, acetic acid, propionic acid, butyric acid and other small molecular acids are will be generated, which can continuously decompose or etch oxide such as ZnO or ZnSeO₃, so as to further decompose and eliminate internal defects of the quantum dots and improve quantum yield of the quantum dots. It should be noted that during repeating the step (2) and step (3) of the preparation process of the cores, each addition amount of the short-chain aliphatic acid zinc and the long-chain aliphatic acid can be respectively the same or different, and the type of the short-chain aliphatic acid zinc and the long-chain aliphatic acid also can be respectively the same or different at each addition.

In some embodiments, the step (2) and step (3) of the preparation process of the cores can be repeated once, or multiple times to obtain CdZnSe quantum dot cores having an average particle size of 3 nm to 10 nm.

In some embodiments, after the first alloy quantum dots growing into the second alloy quantum dots, a thickness of growth is less than or equal to 1.5 nm. And after the (n+1)th alloy quantum dots growing into the (n+2)th alloy quantum dots, a thickness of growth is less than or equal to 1.5 nm for each repetition.

In order to make the reaction of the long-chain aliphatic acid zinc in the second intermediate solution and the third selenium precursor sufficient, and the thickness of further growth of the alloy quantum dots is less than or equal to 1.5 nm after repeating the step (2) and step (3) of the preparation process of the cores each time. In some embodiments, a molarity of the selenium element in the third selenium precursor is from 0.5 mmol/mL to 4 mmol/mL, and a molar ratio of selenium element in the third selenium precursor with respect to zinc element in the second intermediate solution is from 1:2 to 2:1. The molarity of the selenium element in the third selenium precursor refers to the molarity of selenium element in the third selenium precursor before the third selenium precursor is added to the second intermediate solution.

In some embodiments, in order to further avoid the excessive long-chain aliphatic acid zinc decomposition into oxidation products, which can affect the internal quality of quantum dots, the molar ratio of selenium element in the third selenium precursor with respect to zinc element in the second intermediate solution is 1:1.

In the step S2, since the activity of Cd element is higher, S element is preferentially reacted with Cd element, therefore, in order to ensure the uniformity of Cd element in CdZnSe shell layer, the first cadmium precursor can be added to the first precursor solution at a constant speed. Further, preferably the first cadmium precursor and the first sulfur precursor can be added separately or together to the first precursor solution at a constant speed.

In addition, since the excessive first zinc precursor is present in the first precursor solution, when the first cadmium precursor is added to the first precursor solution, the excessive Zn element in the first precursor solution can inhibit the activity of Cd element to ensure the uniform growth of CdZnS shell layer.

In some embodiments, the first cadmium precursor and the first sulfur precursor may be added to the first precursor solution at a constant speed, respectively. In order to simplify the operation process, preferably the first cadmium precursor and the first sulfur precursor are mixed together and added to the first precursor solution at a uniform speed. Based on the amount of the first sulfur precursor, the speed of adding the first cadmium precursor and the first sulfur precursor can be from 2 mmol/h to 4 mmol/h.

In some embodiments, the first zinc precursor includes a long-chain aliphatic acid zinc having a carbon chain greater than or equal to 12. In some embodiments, the first zinc precursor may include a short-chain aliphatic acid zinc having a carbon chain less than or equal to 8 and a long-chain aliphatic acid having a carbon chain greater than or equal to 12, wherein the short-chain aliphatic acid zinc having a carbon chain less than or equal to 8 may include at least one of zinc formate, zinc acetate, zinc propionate, and zinc butyrate, but not limited thereto, preferably the short-chain aliphatic acid zinc includes at least one of zinc formate, zinc acetate, and zinc propionic. The long-chain aliphatic acid having a carbon chain greater than or equal to 12 includes at least one of oleic acid, stearic acid, and isostearic acid, but is not limited thereto. The two react to generate a long-chain aliphatic acid zinc having a carbon chain greater than or equal to 12.

In some embodiments, the cores, the short-chain aliphatic acid zinc, the long-chain aliphatic acid and the solvent are mixed, and reacted at a temperature of 150° C. to 240° C., and then the aliphatic amine is added after generating the long-chain aliphatic acid zinc precursor, so that the first precursor solution is formed.

In some embodiments, the aliphatic amine can be an aliphatic amine having a carbon chain greater than or equal to 8, including at least one of octylamine, dodecylamine, oleylamine, and octadecylamine, but is not limited thereto. The first sulfur precursor can be an elemental sulfur which is soluble in alkylphosphine, including at least one of S-TBP, S-TOP, S-DPP, but is not limited thereto.

In some embodiments, in the step S3, the first temperature is from 290° C., to 310° C., preferably is 300° C. In the above first temperature range, Cd and S elements in the second precursor solution react with Zn element, which can be conducive to the formation of the homogeneous CdZnS shell layer coating on the surface of the core.

It shall be understood that the carbon chain in the short-chain aliphatic acid less than 8 refers to the main carbon chain of the aliphatic acid zinc, and the carbon chain in the long-chain aliphatic acid greater than or equal to 12 refers to the main carbon chain of the aliphatic acid, the carbon chain in the aliphatic amine greater than or equal to 8 refers to the main carbon chain of the aliphatic amine.

The present disclosure also provides another preparation method of quantum dots, including:

S1′, preparing cores;

S2′, mixing the cores, a zinc precursor, an aliphatic alcohol and a solvent to form a first precursor solution, and then at a constant speed adding a first cadmium precursor and a first sulfur precursor separately or together to the first precursor solution to form a second precursor solution, wherein a molar ratio of Cd element with respect to S element in the second precursor solution is from 0.15:1 to 0.4:1;

S3′, performing a reaction of the second precursor solution at a first temperature to form a shell layer covering a surface of the core, and obtaining quantum dots.

In some embodiments, the aliphatic alcohol is selected from the group consisting of aliphatic alcohols having a carbon chain length of 12 to 30.

In some embodiments, the aliphatic alcohol is selected from one or more of dodecyl alcohol, hexadecanol, octadecanol, docosanol, and triacontanol, but is not limited thereto.

In some embodiments, the process of preparing the cores includes: mixing a second zinc precursor, a first selenium precursor, a second cadmium precursor and a solvent, reacting at a second temperature to obtain a solution containing first alloy quantum dots, and purifying the first alloy quantum dots for use as the cores.

In some embodiments, the process of preparing the cores further includes: after the reaction at the second temperature, adding a second selenium precursor, and reacting at a third temperature to obtain a solution containing the first alloy quantum dots.

In some embodiments, the process of preparing the cores further includes: (1) using the solution containing the first alloy quantum dots as a first intermediate solution; (2) mixing the first intermediate solution, a short chain aliphatic acid zinc having a carbon chain length less than or equal to 8, and a long chain aliphatic acid having a carbon chain length greater than or equal to 12, and reacting at a fourth temperature to obtain a second intermediate solution; (3) mixing the second intermediate solution and a third selenium precursor, and reacting at a fifth temperature, so that the first alloy quantum dots can continue to grow, obtaining a solution containing second alloy quantum dots; (4) purifying the second alloy quantum dots for use as the cores.

In some embodiments, the step (2) and the step (3) are repeated at least n times to continue to grow, at ith repetition, the first intermediate solution of the step (1) is replaced with a solution of (i+1)th alloy quantum dots to obtain a solution containing (i+2)th alloy quantum dots, and the (i+2)th alloy quantum dots are purified for use as the cores, wherein the n is a positive integer greater than or equal to 1, and the i is a positive integer less than the n.

In some embodiments, a molar ratio of the long chain aliphatic acid with respect to the short chain aliphatic acid zinc is greater than or equal to 2:1.

In some embodiments, the molar ratio of the long chain aliphatic acid with respect to the short chain aliphatic acid zinc is from 2:1 to 4:1.

In some embodiments, a molar ratio of selenium element in the third selenium precursor with respect to zinc element in the second intermediate solution is from 1:2 to 2:1, and a molarity of the selenium element in the third selenium precursor is from 0.5 mmol/mL to 4 mmol/mL.

In some embodiments, after the first alloy quantum dots growing into the second alloy quantum dots, a thickness of growth is less than or equal to 1.5 nm; and after the (n+1)th alloy quantum dots growing into the (n+2)th alloy quantum dots, a thickness of growth is less than or equal to 1.5 nm for each repetition.

The present disclosure also provides a quantum dot composition including the aforesaid quantum dot, or the quantum dots prepared by the aforesaid preparation method. The quantum dot composition can be an optical material, a color conversion material, an ink, a coating, a label agent, a luminescent material, etc.

In some embodiments, the quantum dot composition can include an adhesive, a polymer colloid, or a solvent.

In some embodiments, the amount of the host material in the quantum dot composition can range from about 80 to about 99.5 percent by weight. Examples of specific host material available include, but are not limited to, a polymer, an oligomer, a monomer, a resin, an adhesive, a glass, a metal oxide, and other non-polymer materials. Preferred host materials can include a polymeric material and a non-polymeric material, which are at least partially transparent, and preferably completely transparent to the preselected wavelength of light.

The present disclosure also provides a photoelectric device, including the aforesaid quantum dot, or the quantum dots prepared by the aforesaid preparation method.

In some embodiments, the photoelectric device can be a quantum dot light conversion film, a quantum dot color film, and its combination with LED devices, quantum dot light emitting diode, etc.

In some embodiments, the photoelectric device is a quantum dot light emitting diode, a working current density required for the quantum dot light emitting diode to achieve the highest external quantum efficiency is from 5 mA/cm² to 20 mA/cm², and the highest external quantum efficiency is from 9.6% to 12.6%.

Therefore, after the quantum dot is applied to the photoelectric device, the EQE can reach its maximum value under a working current density of 5 to 20 mA/cm². Due to the low working current density required by the photoelectric device, the photoelectric device has a relatively long lifetime and can better meet the actual commercialization requirements of blue QLED.

Hereinafter, the quantum dot and the preparation method, the quantum dot composition, and the photoelectric device will be further explained by the following specific embodiments.

### Example 1

2 mmol zinc carbonate basic, 1.4 mL oleic acid and 12 g octadecene were heated to 280° C. under the protection of nitrogen atmosphere to form a clear solution. Then 1.0 mL of 0.5 mmol/mL selenium-octadecene suspension and 0.2 mL of 0.2 mmol/mL cadmium oleate-octadecene were successively injected. Then the temperature was raised to 300° C., 0.5 mL of 2 mmol/mL selenium-tri-n-butyl phosphine solution was added, and the temperature was raised to 310° C. and the reaction was performed for 20 min. After purification, CdZnSe quantum dots with an average particle size of 4.0 nm were obtained and dissolved in 10 mL octadecene for later use.

5.0 mL of the above CdZnSe quantum dot solution, 10 mmol zinc acetate, 25 mmol oleic acid and 10 g octadecene were mixed, and heated to 150° C. for 30 min of reaction under nitrogen protection. Then 1 mL oleylamine was added, the temperature was raised to 300° C., a Cd-ODE-S-TBP mixture (9 mL of 0.1 mmol/mL cadmium oleate-octadecene solution mixed with 3 mL of 2 mmol/mL sulfur-tri-n-butyl phosphine, the molar ratio of cadmium element relative to sulfur element was 0.15:1) was dropwise added, and the dropping speed was 4 mL/h. After completion of the reaction, it was cooled down to room temperature, purified to obtain CdZnSe/CdZnS quantum dots, wherein the CdZnSe core had an average particle diameter of 4 nm, and the thickness of the CdZnS shell layer was 6 nm, and the molar ratio of the cadmium element to sulfur element in the CdZnS shell was 0.15:1.

### Example 2

2 mmol zinc carbonate basic, 1.4 mL oleic acid and 12 g octadecene were heated to 280° C. under the protection of nitrogen atmosphere to form a clear solution. Then 1.0 mL of 0.5 mmol/mL selenium-octadecene suspension and 0.4 mL of 0.2 mmol/mL cadmium oleate-octadecene were successively injected. Then the temperature was raised to 300° C., 0.5 mL of 2 mmol/mL selenium-tri-n-butyl phosphine solution was added, and the temperature was raised to 310° C. and the reaction was performed for 60 min. After purification, CdZnSe quantum dots with an average particle size of 5.5 nm were obtained and dissolved in 10 mL octadecene for later use.

5.0 mL of the above CdZnSe quantum dot solution, 10 mmol zinc acetate, 25 mmol oleic acid and 10 g octadecene were mixed, and heated to 150° C. for 30 min of reaction under nitrogen protection. Then 1 g octadecylamine was added, the temperature was raised to 300° C., a Cd-ODE-S-TBP mixture (8 mL of 0.1 mmol/mL cadmium oleate-octadecene solution mixed with 2 mL of 2 mmol/mL sulfur-tri-n-butyl phosphine, the molar ratio of cadmium to sulfur was 0.2:1) was dropwise added, and the dropping speed was 5 mL/h. After completion of the reaction, it was cooled down to room temperature, purified to obtain CdZnSe/CdZnS quantum dots, wherein the CdZnSe core had an average particle diameter of 5.5 nm, and the thickness of the CdZnS shell layer was 3 nm, and the molar ratio of the cadmium element to sulfur element in the CdZnS shell was 0.2:1.

### Example 3

2 mmol zinc carbonate basic, 1.4 mL oleic acid and 12 g octadecene were heated to 280° C. under the protection of nitrogen atmosphere to form a clear solution. Then 1.0 mL of 0.5 mmol/mL selenium-octadecene suspension and 0.7 mL of 0.2 mmol/mL cadmium oleate-octadecene were successively injected. Then the temperature was raised to 300° C., 0.5 mL of 2 mmol/mL selenium-tri-n-butyl phosphine solution was added, and the temperature was raised to 310° C. and the reaction was performed for 90 min.

The above solution was cooled down to room temperature, 3 mmol zinc acetate and 7.5 mmol oleic acid were added under nitrogen protection, then heated to 180° C. and purged with nitrogen for 30 min. Then 1.5 mL of 2 mmol/mL selenium-tri-n-butyl phosphine solution was added, and heated to 310° C. and the reaction was performed for 30 min. After purification, CdZnSe quantum dots with an average particle size of 7.0 nm were obtained and dissolved in 10 mL octadecene for later use.

5.0 mL of the above CdZnSe quantum dot solution, 10 mmol zinc acetate, 25 mmol oleic acid and 10 g octadecene were mixed, and heated to 150° C. for 30 min of reaction under nitrogen protection. Then 1 mL oleylamine was added, the temperature was raised to 300° C., a Cd-ODE-S-TBP mixture (6 mL of 0.1 mmol/mL cadmium oleate-octadecene solution mixed with 2 mL of 2 mmol/mL sulfur-tri-n-butyl phosphine, the molar ratio of cadmium to sulfur was 0.15:1) was dropwise added, and the dropping speed was 4 mL/h. After completion of the reaction, it was cooled down to room temperature, purified to obtain CdZnSe/CdZnS quantum dots, wherein the CdZnSe core had an average particle diameter of 7 nm, and the thickness of the CdZnS shell layer was 3 nm, and the molar ratio of the cadmium element to sulfur element in the CdZnS shell was 0.15:1.

### Example 4

2 mmol zinc carbonate basic, 1.4 mL oleic acid and 12 g octadecene were heated to 280° C. under the protection of nitrogen atmosphere to form a clear solution. Then 1.0 mL of 0.5 mmol/mL selenium-octadecene suspension and 0.4 mL of 0.2 mmol/mL cadmium stearate-octadecene were successively injected. Then the temperature was raised to 300° C., 0.5 mL of 2 mmol/mL selenium-tri-n-butyl phosphine solution was added, and the temperature was raised to 310° C. and the reaction was performed for 90 min.

The above solution was cooled down to room temperature, 3 mmol zinc propionate and 7.5 mmol stearic acid were added under nitrogen protection, then heated to 180° C. and purged with nitrogen for 30 min. Then 1.5 mL of 2 mmol/mL selenium-tri-n-butyl phosphine solution was added, and heated to 310° C. and the reaction was performed for 30 min. After purification, CdZnSe quantum dots with an average particle size of 7.0 nm were obtained and dissolved in 10 mL octadecene for later use.

5.0 mL of the above CdZnSe quantum dot solution, 10 mmol zinc acetate, 25 mmol oleic acid and 10 g octadecene were mixed, and heated to 150° C. for 30 min of reaction under nitrogen protection. Then 0.5 mL n-octylamine was added, the temperature was raised to 300° C., a Cd-ODE-S-TBP mixture (7.5 mL of 0.2 mmol/mL cadmium oleate-octadecene solution mixed with 3 mL of 2 mmol/mL sulfur-tri-n-butyl phosphine, the molar ratio of cadmium to sulfur was 0.25:1) was dropwise added, and the dropping speed was 5 mL/h. After completion of the reaction, it was cooled down to room temperature, purified to obtain CdZnSe/CdZnS quantum dots, wherein the CdZnSe core had an average particle diameter of 7 nm, and the thickness of the CdZnS shell layer was 6 nm, and the molar ratio of the cadmium element to sulfur element in the CdZnS shell was 0.25:1.

### Example 5

2 mmol zinc carbonate basic, 1.4 mL oleic acid and 12 g octadecene were heated to 280° C. under the protection of nitrogen atmosphere to form a clear solution. Then 1.0 mL of 0.5 mmol/mL selenium-octadecene suspension and 0.4 mL of 0.2 mmol/mL cadmium oleate-octadecene were successively injected. Then the temperature was raised to 300° C., 0.5 mL of 2 mmol/mL selenium-tri-n-butyl phosphine solution was added, and the temperature was raised to 310° C. and the reaction was performed for 90 min.

The above solution was cooled down to room temperature, 3 mmol zinc propionate and 7.5 mmol stearic acid were added under nitrogen protection, then heated to 180° C. and purged with nitrogen for 30 min. Then 1.5 mL of 2 mmol/mL selenium-tri-n-butyl phosphine solution was added, and heated to 310° C. and the reaction was performed for 30 min.

The above solution was cooled down to room temperature, 2 mmol zinc acetate and 5 mmol stearic acid were added under nitrogen protection, then heated to 180° C. and purged with nitrogen for 30 min. Then 1 mL of 2 mmol/mL selenium-tri-n-butyl phosphine solution was added, and heated to 310° C. and the reaction was performed for 30 min. After purification, CdZnSe quantum dots with an average particle size of 8 nm were obtained and dissolved in 10 mL octadecene for later use.

5.0 mL of the above CdZnSe quantum dot solution, 10 mmol zinc acetate, 25 mmol oleic acid and 10 g octadecene were mixed, and heated to 150° C. for 30 min of reaction under nitrogen protection. Then 1 mL oleylamine was added, the temperature was raised to 300° C., a Cd-ODE-S-TBP mixture (9 mL of 0.2 mmol/mL cadmium oleate-octadecene solution mixed with 3 mL of 2 mmol/mL sulfur-tri-n-butyl phosphine, the molar ratio of cadmium to sulfur was 0.3:1) was dropwise added, and the dropping speed was 5 mL/h. After completion of the reaction, it was cooled down to room temperature, purified to obtain CdZnSe/CdZnS quantum dots, wherein the CdZnSe core had an average particle diameter of 8 nm, and the thickness of the CdZnS shell layer was 4 nm, and the molar ratio of the cadmium element to sulfur element in the CdZnS shell was 0.3:1.

### Example 6

2 mmol zinc carbonate basic, 1.4 mL oleic acid and 12 g octadecene were heated to 280° C. under the protection of nitrogen atmosphere to form a clear solution. Then 1.0 mL of 0.5 mmol/mL selenium-octadecene suspension and 0.3 mL of 0.2 mmol/mL cadmium tetradecanoate-octadecene were successively injected. Then the temperature was raised to 300° C., 0.5 mL of 2 mmol/mL selenium-tri-n-butyl phosphine solution was added, and the temperature was raised to 310° C. and the reaction was performed for 90 min.

The above solution was cooled down to room temperature, 3 mmol zinc formate and 7.5 mmol dodecanoic acid were added under nitrogen protection, then heated to 150° C. and purged with nitrogen for 30 min. Then 1.5 mL of 2 mmol/mL selenium-tri-n-butyl phosphine solution was added, and heated to 310° C. and the reaction was performed for 30 min.

The above solution was cooled down to room temperature, 4 mmol zinc propionate and 10 mmol oleic acid were added under nitrogen protection, then heated to 180° C. and purged with nitrogen for 30 min. Then 2 mL of 2 mmol/mL selenium-tri-n-butyl phosphine solution was added, and heated to 310° C. and the reaction was performed for 30 min.

The above solution was cooled down to room temperature, 5 mmol zinc caprylate and 12.5 mmol stearic acid were added under nitrogen protection, then heated to 240° C. and purged with nitrogen for 30 min. Then 2.5 mL of 2 mmol/mL selenium-tri-n-octyl phosphine solution was added, and heated to 310° C. and the reaction was performed for 30 min. After purification, CdZnSe quantum dots with an average particle size of 10 nm were obtained and dissolved in 10 mL octadecene for later use.

5.0 mL of the above CdZnSe quantum dot solution, 10 mmol zinc acetate, 25 mmol oleic acid and 10 g octadecene were mixed, and heated to 150° C. for 30 min of reaction under nitrogen protection. Then 1 mL oleylamine was added, the temperature was raised to 300° C., a Cd-ODE-S-TBP mixture (12 mL of 0.2 mmol/mL cadmium oleate-octadecene solution mixed with 3 mL of 2 mmol/mL sulfur-tri-n-butyl phosphine, the molar ratio of cadmium to sulfur was 0.4:1) was dropwise added, and the dropping speed was 5 mL/h. After completion of the reaction, it was cooled down to room temperature, purified to obtain CdZnSe/CdZnS quantum dots, wherein the CdZnSe core had an average particle diameter of 10 nm, and the thickness of the CdZnS shell layer was 3 nm, and the molar ratio of the cadmium element to sulfur element in the CdZnS shell was 0.4:1.

### Example 7

2 mmol zinc carbonate basic, 1.4 mL oleic acid and 12 g octadecene were heated to 280° C. under the protection of nitrogen atmosphere to form a clear solution. Then 1.2 mL of 0.5 mmol/mL selenium-octadecene suspension and 0.2 mL of 0.2 mmol/mL cadmium dodecanoate-octadecene were successively injected. Then the temperature was raised to 300° C., 0.5 mL of 2 mmol/mL selenium-tri-n-butyl phosphine solution was added, and the temperature was raised to 310° C. and the reaction was performed for 20 min. After purification, CdZnSe quantum dots with an average particle size of 3.0 nm were obtained and dissolved in 10 mL octadecene for later use.

5.0 mL of the above CdZnSe quantum dot solution, 10 mmol zinc acetate, 25 mmol oleic acid and 10 g octadecene were mixed, and heated to 150° C. for 30 min of reaction under nitrogen protection. Then 1 g dodecylamine was added, the temperature was raised to 300° C., a Cd-ODE-S-TBP mixture (6 mL of 0.2 mmol/mL cadmium oleate-octadecene solution mixed with 4 mL of 2 mmol/mL sulfur-tri-n-butyl phosphine, the molar ratio of cadmium to sulfur was 0.15:1) was dropwise added, and the dropping speed was 5 mL/h. After completion of the reaction, it was cooled down to room temperature, purified to obtain CdZnSe/CdZnS quantum dots, wherein the CdZnSe core had an average particle diameter of 3 nm, and the thickness of the CdZnS shell layer was 10 nm, and the molar ratio of the cadmium element to sulfur element in the CdZnS shell was 0.15:1.

### Example 8

2 mmol zinc carbonate basic, 1.4 mL oleic acid and 12 g octadecene were heated to 280° C. under the protection of nitrogen atmosphere to form a clear solution. Then 1.2 mL of 0.5 mmol/mL selenium-octadecene suspension and 0.2 mL of 0.2 mmol/mL cadmium oleate-octadecene were successively injected. Then the temperature was raised to 310° C. and the reaction was performed for 90 min. After purification, CdZnSe quantum dots with an average particle size of 3.5 nm were obtained and dissolved in 10 mL octadecene for later use.

5.0 mL of the above CdZnSe quantum dot solution, 10 mmol zinc acetate, 25 mmol oleic acid and 10 g octadecene were mixed, and heated to 150° C. for 30 min of reaction under nitrogen protection. Then 1 mL oleylamine was added, the temperature was raised to 300° C., a Cd-ODE-S-TBP mixture (3 mL of 0.2 mmol/mL cadmium oleate-octadecene solution mixed with 2 mL of 2 mmol/mL sulfur-tri-n-butyl phosphine, the molar ratio of cadmium to sulfur was 0.15:1) was dropwise added, and the dropping speed was 2.5 mL/h. After completion of the reaction, it was cooled down to room temperature, purified to obtain CdZnSe/CdZnS quantum dots, wherein the CdZnSe core had an average particle diameter of 3.5 nm, and the thickness of the CdZnS shell layer was 4.5 nm, and the molar ratio of the cadmium element to sulfur element in the CdZnS shell was 0.15:1.

### Example 9

The difference between this example and Example 3 is only that “1 mL oleylamine was added” is replaced with “1 g octadecanol was added” in the reaction step of coating the CdZnS shell layer.

### Example 10

The difference between this example and Example 6 is only that “1 mL oleylamine was added” is replaced with “0.8 g hexadecanol was added” in the reaction step of coating the CdZnS shell layer.

### Comparative Example 1

2 mmol zinc carbonate basic, 1.4 mL oleic acid and 12 g octadecene were heated to 280° C. under the protection of nitrogen atmosphere to form a clear solution. Then 1.0 mL of 0.5 mmol/mL selenium-octadecene suspension and 0.7 mL of 0.2 mmol/mL cadmium oleate-octadecene were successively injected. Then the temperature was raised to 300° C., 0.5 mL of 2 mmol/mL selenium-tri-n-butyl phosphine solution was added, and the temperature was raised to 310° C. and the reaction was performed for 90 min.

The above solution was cooled down to room temperature, 3 mmol zinc acetate and 7.5 mmol oleic acid were added under nitrogen protection, then heated to 180° C. and purged with nitrogen for 30 min. Then 1.5 mL of 2 mmol/mL selenium-tri-n-butyl phosphine solution was added, and heated to 310° C. and the reaction was performed for 30 min. After purification, CdZnSe quantum dots with an average particle size of 7.0 nm were obtained and dissolved in 10 mL octadecene for later use.

5.0 mL of the above CdZnSe quantum dot solution, 10 mmol zinc acetate, 25 mmol oleic acid and 10 g octadecene were mixed, and heated to 150° C. for 30 min of reaction under nitrogen protection. Then 1 mL oleylamine was added, the temperature was raised to 300° C., a Cd-ODE-S-TBP mixture (6.25 mL of 0.08 mmol/mL cadmium oleate-octadecene solution mixed with 2 mL of 2 mmol/mL sulfur-tri-n-butyl phosphine, the molar ratio of cadmium to sulfur was 0.125:1) was dropwise added, and the dropping speed was 4 mL/h. After completion of the reaction, it was cooled down to room temperature, purified to obtain CdZnSe/CdZnS quantum dots, wherein the CdZnSe core had an average particle diameter of 7 nm, and the thickness of the CdZnS shell layer was 3 nm, and the molar ratio of the cadmium element to sulfur element in the CdZnS shell was 0.125:1.

### Comparative Example 2

2 mmol zinc carbonate basic, 1.4 mL oleic acid and 12 g octadecene were heated to 280° C. under the protection of nitrogen atmosphere to form a clear solution. Then 1.0 mL of 0.5 mmol/mL selenium-octadecene suspension and 0.7 mL of 0.2 mmol/mL cadmium oleate-octadecene were successively injected. Then the temperature was raised to 300° C., 0.5 mL of 2 mmol/mL selenium-tri-n-butyl phosphine solution was added, and the temperature was raised to 310° C. and the reaction was performed for 90 min.

The above solution was cooled down to room temperature, 3 mmol zinc acetate and 7.5 mmol oleic acid were added under nitrogen protection, then heated to 180° C. and purged with nitrogen for 30 min. Then 1.5 mL of 2 mmol/mL selenium-tri-n-butyl phosphine solution was added, and heated to 310° C. and the reaction was performed for 30 min. After purification, CdZnSe quantum dots with an average particle size of 7.0 nm were obtained and dissolved in 10 mL octadecene for later use.

5.0 mL of the above CdZnSe quantum dot solution, 10 mmol zinc acetate, 25 mmol oleic acid and 10 g octadecene were mixed, and heated to 150° C. for 30 min of reaction under nitrogen protection. Then 1 mL oleylamine was added, the temperature was raised to 300° C., a Cd-ODE-S-TBP mixture (8 mL of 0.05 mmol/mL cadmium oleate-octadecene solution mixed with 2 mL of 2 mmol/mL sulfur-tri-n-butyl phosphine, the molar ratio of cadmium to sulfur was 0.1:1) was dropwise added, and the dropping speed was 5 mL/h. After completion of the reaction, it was cooled down to room temperature, purified to obtain CdZnSe/CdZnS quantum dots, wherein the CdZnSe core had an average particle diameter of 7 nm, and the thickness of the CdZnS shell layer was 3 nm, and the molar ratio of the cadmium element to sulfur element in the CdZnS shell was 0.1:1.

### Comparative Example 3

2 mmol zinc carbonate basic, 1.4 mL oleic acid and 12 g octadecene were heated to 280° C. under the protection of nitrogen atmosphere to form a clear solution. Then 1.0 mL of 0.5 mmol/mL selenium-octadecene suspension and 0.8 mL of 0.2 mmol/mL cadmium oleate-octadecene were successively injected. Then the temperature was raised to 300° C., 0.5 mL of 2 mmol/mL selenium-tri-n-butyl phosphine solution was added, and the temperature was raised to 310° C. and the reaction was performed for 90 min.

The above solution was cooled down to room temperature, 3 mmol zinc acetate and 7.5 mmol oleic acid were added under nitrogen protection, then heated to 180° C. and purged with nitrogen for 30 min. Then 1.5 mL of 2 mmol/mL selenium-tri-n-butyl phosphine solution was added, and heated to 310° C. and the reaction was performed for 30 min. After purification, CdZnSe quantum dots with an average particle size of 7.0 nm were obtained and dissolved in 10 mL octadecene for later use.

5.0 mL of the above CdZnSe quantum dot solution, 10 mmol zinc acetate, 25 mmol oleic acid and 10 g octadecene were mixed, and heated to 150° C. for 30 min of reaction under nitrogen protection. Then 1 mL oleylamine was added, the temperature was raised to 300° C., a ODE-S-TBP mixture (6 mL octadecene mixed with 2 mL of 2 mmol/mL sulfur-tri-n-butyl phosphine) was dropwise added, and the dropping speed was 4 mL/h. After completion of the reaction, it was cooled down to room temperature, purified to obtain CdZnSe/CdZnS quantum dots, wherein the CdZnSe core had an average particle diameter of 7 nm, and the thickness of the CdZnS shell layer was 3 nm.

### Comparative Example 4

2 mmol zinc carbonate basic, 1.4 mL oleic acid and 12 g octadecene were heated to 280° C. under the protection of nitrogen atmosphere to form a clear solution. Then 1.0 mL of 0.5 mmol/mL selenium-octadecene suspension and 0.7 mL of 0.2 mmol/mL cadmium oleate-octadecene were successively injected. Then the temperature was raised to 300° C., 0.5 mL of 2 mmol/mL selenium-tri-n-butyl phosphine solution was added, and the temperature was raised to 310° C. and the reaction was performed for 90 min.

The above solution was cooled down to room temperature, 3 mmol zinc acetate and 7.5 mmol oleic acid were added under nitrogen protection, then heated to 180° C. and purged with nitrogen for 30 min. Then 1.5 mL of 2 mmol/mL selenium-tri-n-butyl phosphine solution was added, and heated to 310° C. and the reaction was performed for 30 min. After purification, CdZnSe quantum dots with an average particle size of 7.0 nm were obtained and dissolved in 10 mL octadecene for later use.

5.0 mL of the above CdZnSe quantum dot solution, 10 mmol zinc acetate, 25 mmol oleic acid and 10 g octadecene were mixed, and heated to 150° C. for 30 min of reaction under nitrogen protection. Then 1 mL oleylamine was added, the temperature was raised to 300° C., a Cd-ODE-S-TBP mixture (10 mL of 0.2 mmol/mL cadmium oleate-octadecene solution mixed with 2 mL of 2 mmol/mL sulfur-tri-n-butyl phosphine, the molar ratio of cadmium to sulfur was 0.5:1) was dropwise added, and the dropping speed was 5 mL/h. After completion of the reaction, it was cooled down to room temperature, purified to obtain CdZnSe/CdZnS quantum dots, wherein the CdZnSe core had an average particle diameter of 7 nm, and the thickness of the CdZnS shell layer was 3 nm, and the molar ratio of the cadmium element to sulfur element in the CdZnS shell was 0.5:1.

The quantum dots of Examples 1 to 10 and Comparative Examples 1 to 4 were used to make photoelectric devices respectively, the structure of the photoelectric devices was ITO/PEDOTS:PSS/TFB/Quantum dots/ZnMgO/Al, and the specific preparation method was as follows:

1. Cleaning ITO Glass Substrate

The ITO glass substrate with marking numbers on the back was put into a glass dish with ethanol solution, and the ITO surface was cleaned with cotton swabs. It was ultrasonic cleaned by acetone, deionized water and ethanol for 10 min respectively, and then dried with nitrogen gun. Finally, the cleaned ITO glass substrate was placed in oxygen plasma for further cleaning for 10 minutes.

2. Hole Injection Layer

In the air, PEDOTS:PSS was spun on the cleaned ITO glass substrate at 3000 r/min for 45 s. After finishing the spin coating, it was annealed in air at 150° C. for 30 min. After the annealing was completed, the substrate was quickly transferred to the glove box in nitrogen atmosphere.

3. Hole Transport Layer

8-10 mg/mL of TFB was spun on the substrate of ITO/PEDOTS:PSS at a rotation speed of 2000 r/min for 45 seconds to form a hole transport layer. After finishing the spin coating, it was annealed in air at 150° C. for 30 min.

4. Quantum Dot Light-Emitting Layer

The core-shell quantum dots, with an optical density of 30˜40 at 350 nm, were dissolved in octane solvent. The quantum dot solution was spun on the annealed ITO/PEDOTS:PSS/TFB, and the spin coating speed was 2000 r/min, and the spin coating time was 45 s. After the spin coating was completed, without annealing, the next layer was spin coated on it.

5. Electron Transport Layer

Spin coating of MgZnO nanocrystalline solution (30 mg/mL, ethanol solution): MgZnO nanocrystalline solution was spun on the substrate of ITO/PEDOTS:PSS/TFB/Quantum dots at 2000 r/min for 45 s.

6. Aluminium Electrode

The prepared sample substrate was placed in a vacuum cavity and the top electrode was formed by vapor deposition. For the first 10 nm of the thickness of the aluminum electrode, the vapor deposition rate was controlled in the range of 0.2˜0.4 Å/s, after the first 10 nm, and the vapor deposition rate was increased to 1.0-2.0 Å/s. The thickness of the aluminum electrode was 100 nm.

The performance of the photoelectric devices made of the quantum dots of Examples 1 to 10 and Comparative Examples 1 to 4 were tested, and the results are shown in Table 1.

Test method for external quantum efficiency:

The current density-voltage curve of the quantum dot light-emitting device was measured by Keithley2400, and the luminance of the photoelectric device was determined by spectrometer (QE-Pro) combined with the integrating sphere (FOIS-1). The external quantum efficiency of the light-emitting device was calculated based on the measured current density and the luminance. External quantum efficiency can represent the ratio between the number of photons emitted by the photoelectric device and the number of electrons injected into the device in the observation direction, which is an important parameter of the luminous efficiency of the photoelectric device. The higher the external quantum efficiency is, the higher the luminous efficiency of the device is.

TABLE 1

| | | | | Current density at |
|---|---|---|---|---|
| | EL/nm | EQE(ave) | T₅₀/h | EQEₘₐₓ |
| Example 1 | 470 | 9.6% | 11000 | 20 mA/cm² |
| Example 2 | 472 | 10.2% | 12500 | 15 mA/cm² |
| Example 3 | 475 | 12.0% | 12000 | 15 mA/cm² |
| Example 4 | 478 | 12.6% | 15200 | 10 mA/cm² |
| Example 5 | 478 | 11.7% | 16000 | 15 mA/cm² |
| Example 6 | 480 | 11.9% | 19500 | 20 mA/cm² |
| Example 7 | 480 | 9.9% | 10500 | 20 mA/cm² |
| Example 8 | 478 | 9.6% | 10250 | 15 mA/cm² |
| Example 9 | 475 | 10.9% | 13500 | 15 mA/cm² |
| Example 10 | 480 | 12.5% | 18000 | 20 mA/cm² |
| Comparative | 475 | 8.0% | 3800 | 50 mA/cm² |
| Example 1 | | | | |
| Comparative | 475 | 7.0% | 2800 | 100 mA/cm² |
| Example 2 | | | | |
| Comparative | 475 | 7.3% | 1800 | 200 mA/cm² |
| Example 3 | | | | |
| Comparative | 497 | 7.2% | 16800 | 50 mA/cm² |
| Example 4 | | | | |

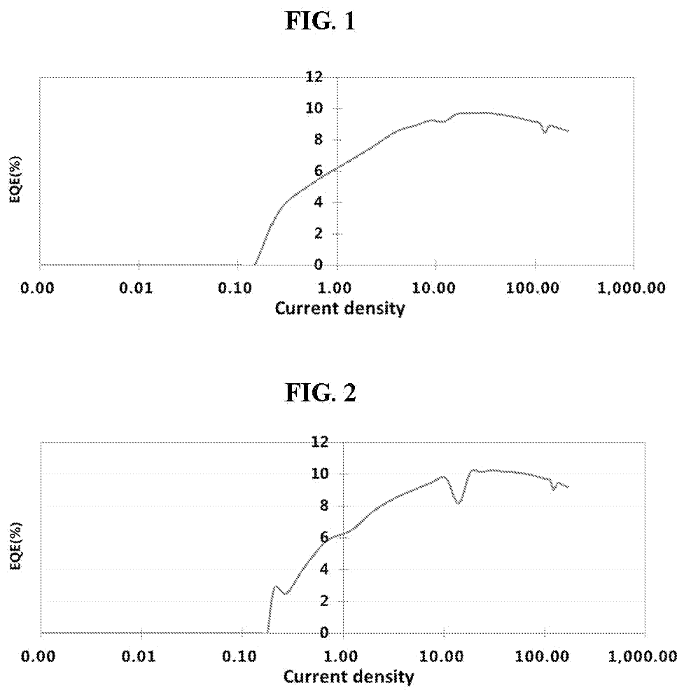

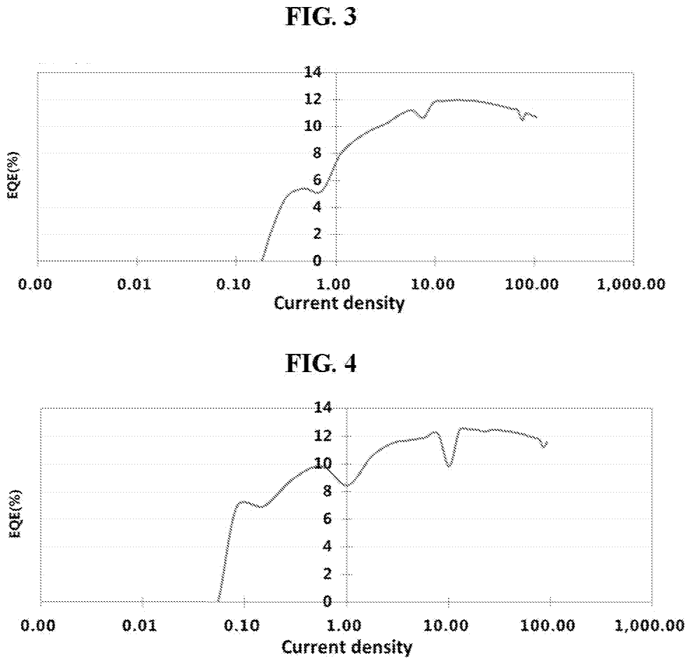

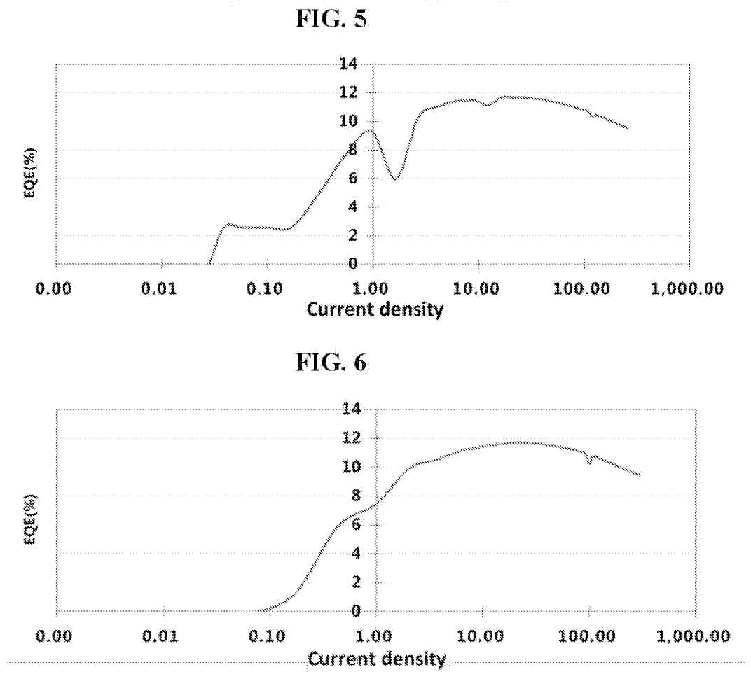

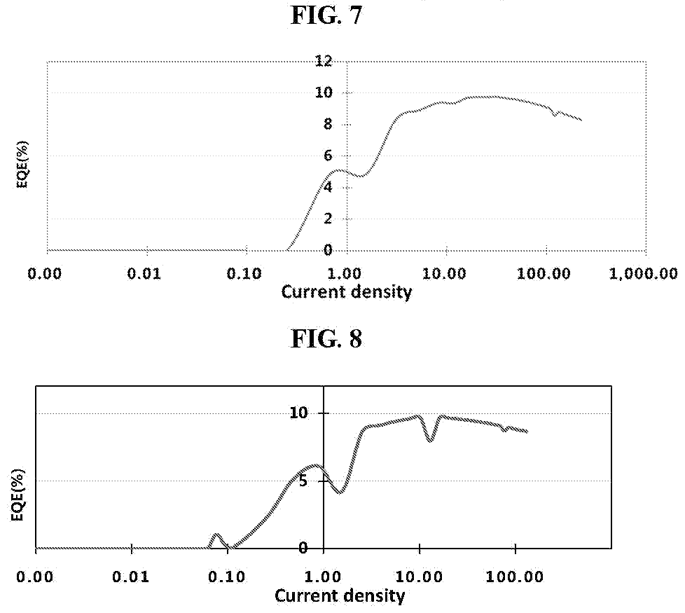

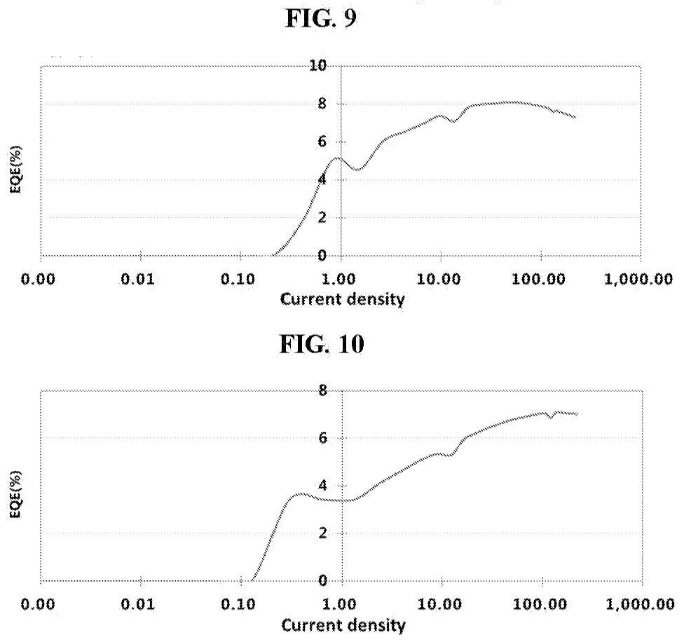

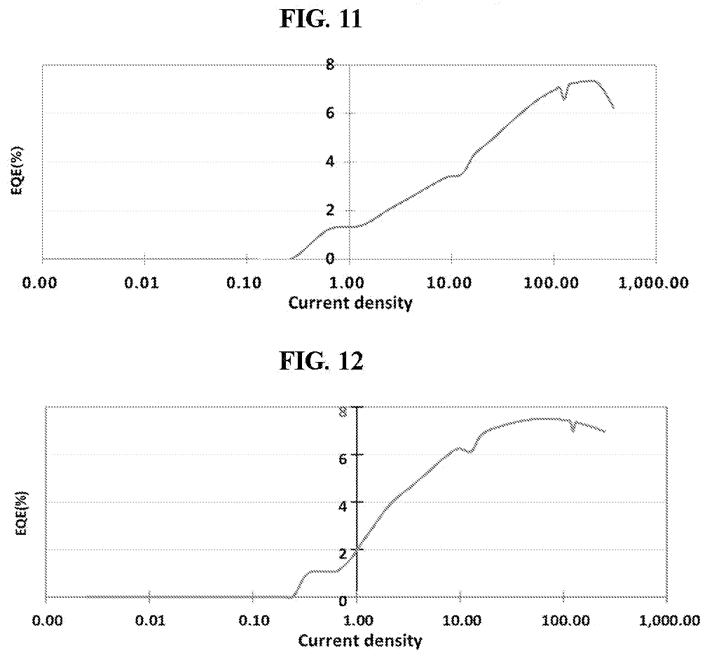

In Table 1, EL refers to the peak wavelength of the emission peak of the photoelectric device, and EQE (ave) refers to the average external quantum efficiency of the photoelectric device, and T₅₀ refers to the aging time required to reduce the luminance of the photoelectric device to 50% of the initial luminance under the luminance condition of 100 cd/m², the current density at EQEₘₐₓ refers to the working current density of the photoelectric device when EQE reaches its maximum value. FIGS. 1 to 12 show the current density curves for each example and comparative example, from which the maximum EQE of the device and the corresponding current density at EQEₘₐₓ can be referred.

As can be seen from Table 1, the photoelectric devices having the quantum dots of the present disclosure could reach its maximum EQE within the working current density range of 5 mA/cm²˜20 mA/cm², and the T₅₀ lifespan can be greater than or equal to 10000 h under the luminance condition of 100 cd/m², i.e., the photoelectric device has high luminous efficiency and high lifespan under the condition of low working current density.

The various technical features of the above examples may be arbitrarily combined, in order to make the description concise, all of the possible combinations of various technical features in the above examples are not described in detail. However, as long as the combination of these technical features does not have contradictions, it should be considered as the scope of this specification.

The foregoing embodiments are only preferred embodiments of the present invention, and cannot be used to limit the scope of protection of the present invention. Any insubstantial changes and substitutions made by those skilled in the art on the basis of the present disclosure belong to the scope of the present invention. The scope of protection is according the claims.

1. A quantum dot, comprising a core and a shell layer covering the core, a material of the core being CdZnSe, and a material of the shell layer being CdZnS, wherein a molar ratio of Cd element with respect to S element in the shell layer is from 0.15:1 to 0.4:1.

2. The quantum dot of claim 1, wherein an average particle diameter of the core is from 3 nm to 10 nm, and a thickness of the shell layer is from 3 nm to 10 nm.

3. The quantum dot of claim 2, wherein the average particle diameter of the core is from 5 nm to 9 nm, and the thickness of the shell layer is from 3 nm to 5 nm.

4. The quantum dot of claim 1, wherein a photoluminescence emission peak wavelength of the quantum dot is from 460 nm to 480 nm.

5. The quantum dot of claim 4, wherein the photoluminescence emission peak wavelength of the quantum dot is from 470 nm to 480 nm.

6. A preparation method for quantum dots of claim 1, comprising:
preparing cores;
mixing the cores, a zinc precursor, an aliphatic amine and a solvent to form a first precursor solution, and then at a constant speed adding a first cadmium precursor and a first sulfur precursor separately or together to the first precursor solution to form a second precursor solution, wherein a molar ratio of Cd element with respect to S element in the second precursor solution is from 0.15:1 to 0.4:1;
performing a reaction of the second precursor solution at a first temperature to form a shell layer covering a surface of the core, and obtaining the quantum dots.

7. The preparation method for quantum dots of claim 6, the process of preparing the cores comprising: mixing a second zinc precursor, a first selenium precursor, a second cadmium precursor and a solvent, reacting at a second temperature to obtain a solution containing first alloy quantum dots, and purifying the first alloy quantum dots for use as the cores.

8. The preparation method for quantum dots of claim 7, the process of preparing the cores further comprising: after the reaction at the second temperature, adding a second selenium precursor, and reacting at a third temperature to obtain a solution containing the first alloy quantum dots.

9. The preparation method for quantum dots of claim 7, the process of preparing the cores further comprising:
(1) using the solution containing the first alloy quantum dots as a first intermediate solution;
(2) mixing the first intermediate solution, a short-chain aliphatic acid zinc having a carbon chain length less than or equal to 8, and a long-chain aliphatic acid having a carbon chain length greater than or equal to 12, and reacting at a fourth temperature to obtain a second intermediate solution;
(3) mixing the second intermediate solution and a third selenium precursor, and reacting at a fifth temperature, so that the first alloy quantum dots can continue to grow, obtaining a solution containing second alloy quantum dots;
(4) purifying the second alloy quantum dots for use as the cores.

10. The preparation method for quantum dots of claim 9, repeating the step (2) and the step (3) at least n times to continue to grow, at nth repetition, replacing the first intermediate solution of the step (1) with a solution of (n+1)th alloy quantum dots to obtain a solution containing (n+2)th alloy quantum dots, and purifying the (n+2)th alloy quantum dots for use as the cores, wherein the n is a positive integer greater than or equal to 1.

11. The preparation method for quantum dots of claim 10, wherein, a molar ratio of the long-chain aliphatic acid with respect to the short-chain aliphatic acid zinc is greater than or equal to 2:1.

12. The preparation method for quantum dots of claim 11, wherein, the molar ratio of the long-chain aliphatic acid with respect to the short-chain aliphatic acid zinc is from 2:1 to 4:1.

13. The preparation method for quantum dots of claim 10, wherein, a molar ratio of selenium element in the third selenium precursor with respect to zinc element in the second intermediate solution is from 1:2 to 2:1, and a molarity of the selenium element in the third selenium precursor is from 0.5 mmol/mL to 4 mmol/mL.

14. The preparation method for quantum dots of claim 10, wherein, after the first alloy quantum dots growing into the second alloy quantum dots, a thickness of growth is less than or equal to 1.5 nm; and after the (n+1)th alloy quantum dots growing into the (n+2)th alloy quantum dots, a thickness of growth is less than or equal to 1.5 nm for each repetition.

15. The preparation method for quantum dots of claim 10, at ith repetition, replacing the first intermediate solution of the step (1) with a solution of (i+1)th alloy quantum dots to obtain a solution containing (i+2)th alloy quantum dots, and purifying the (i+2)th alloy quantum dots for use as the cores, wherein the i is a positive integer less than the n.

16. A preparation method for quantum dots of claim 1, comprising:
preparing cores;
mixing the cores, a zinc precursor, an aliphatic alcohol and a solvent to form a first precursor solution, and then at a constant speed adding a first cadmium precursor and a first sulfur precursor separately or together to the first precursor solution to form a second precursor solution, wherein a molar ratio of Cd element with respect to S element in the second precursor solution is from 0.15:1 to 0.4:1;
performing a reaction of the second precursor solution at a first temperature to form a shell layer covering a surface of the core, and obtaining the quantum dots.

17. A The preparation method for quantum dots of claim 16, wherein, the aliphatic alcohol is selected from the group of aliphatic alcohols with carbon chain length of 12 to 30.

18. (canceled)

19. A photoelectric device, comprising the quantum dot according to claim 1.

20. The photoelectric device of claim 19, wherein, the photoelectric device is a quantum dot light emitting diode, a working current density required for the quantum dot light emitting diode to achieve the highest external quantum efficiency is from 5 mA/cm² to 20 mA/cm², and the highest external quantum efficiency is from 9.6% to 12.6%.

21. The preparation method for quantum dots of claim 8, the process of preparing the cores further comprising:
(1) using the solution containing the first alloy quantum dots as a first intermediate solution;
(2) mixing the first intermediate solution, a short-chain aliphatic acid zinc having a carbon chain length less than or equal to 8, and a long-chain aliphatic acid having a carbon chain length greater than or equal to 12, and reacting at a fourth temperature to obtain a second intermediate solution;
(3) mixing the second intermediate solution and a third selenium precursor, and reacting at a fifth temperature, so that the first alloy quantum dots can continue to grow, obtaining a solution containing second alloy quantum dots;
(4) purifying the second alloy quantum dots for use as the cores.
